(19) United States
(12) Patent Application Publication
(10) Pub. No.: US 2014/0094015 A1
(43) Pub. Date: Apr. 3, 2014

(54) ALIGNMENT MEASUREMENT SYSTEM, OVERLAY MEASUREMENT SYSTEM, AND METHOD FOR MANUFACTURING SEMICONDUCTOR DEVICE

(71) Applicant: KABUSHIKI KAISHA TOSHIBA, Tokyo (JP)

(72) Inventors: Kentaro KASA, Kanagawa-ken (JP); Manabu TAKAKUWA, Mie-ken (JP); Masato SUZUKI, Kanagawa-ken (JP); Shizuo KINOSHITA, Kanagawa-ken (JP)

(73) Assignee: Kabushiki Kaisha Toshiba, Tokyo (JP)

(21) Appl. No.: 13/771,968

(22) Filed: Feb. 20, 2013

(30) Foreign Application Priority Data
Sep. 28, 2012 (JP) 2012-216356

(51) Int. Cl. H01L 21/66; G01B 11/26

(52) U.S. Cl. CPC H01L 22/12; G01B 11/26
USPC 438/401; 356/401

(57) ABSTRACT

According to one embodiment, an alignment measurement system is configured to measure a position of a mark having the highest identifiability of a plurality of marks formed in a substrate. The plurality of marks are made of mutually different patterns. A device pattern is formed in the substrate using directed self-assembly after the plurality of marks is formed.

### CROSS-REFERENCE TO RELATED APPLICATIONS

This application is based upon and claims the benefit of priority from the prior Japanese Patent Application No. 2012-216356, filed on Sep. 28, 2012; the entire contents of which are incorporated herein by reference.

### FIELD

Embodiments described herein relate generally to an alignment measurement system, overlay measurement system, and a method for manufacturing a semiconductor device.

### BACKGROUND

Normally, a semiconductor device is manufactured by multiply repeating processes that form device patterns such as interconnects, contacts, etc., on a wafer. Therefore, when forming one device pattern, it is necessary to accurately ascertain the position of the device pattern formed previously. Also, after forming multiple device patterns by overlaying, it is necessary to evaluate the precision of the overlay. Therefore, an alignment mark for alignment also is formed when forming the device patterns.

On the other hand, in recent years, higher integration of semiconductor devices has progressed; and it has become necessary to form fine patterns exceeding the limits of photolithography. Therefore, several techniques that can form fine patterns have been proposed to replace photolithography. So-called DSA (Directed Self Assembly) technique which forms a pattern by utilizing a micro phase separation of a high polymer is drawing attention as one such technique.

### BRIEF DESCRIPTION OF THE DRAWINGS

FIG. 1 is a block diagram showing an alignment measurement system according to a first embodiment;

FIG. 2 is a flowchart showing the method for manufacturing the semiconductor device according to the first embodiment;

FIGS. 3A and 3B are cross-sectional views showing a wafer, FIG. 3A shows an alignment mark region, and FIG. 3B shows a device region;

FIG. 4 is a plan view showing a reticle;

FIGS. 5A to 5D are plan views respectively showing the regions A to D shown in FIG. 4;

FIGS. 6A to 6G are schematic cross-sectional views showing the method for manufacturing the semiconductor device according to the first embodiment;

FIG. 7 is a plan view showing the alignment marks formed in the wafer;

FIG. 8 is a block diagram showing an overlay measurement system according to a second embodiment;

FIG. 9 is a flowchart showing the method for manufacturing the semiconductor device according to the second embodiment;

FIG. 10A is a plan view showing the reticle when forming the alignment marks, and FIG. 10B is a plan view showing the reticle when forming the litholayer marks; and

FIG. 11 is a plan view showing the alignment marks and the litholayer marks formed in the wafer.

### DETAILED DESCRIPTION

In general, according to one embodiment, an alignment measurement system is configured to measure a position of a mark having the highest identifiability of a plurality of marks formed in a substrate. The plurality of marks are made of mutually different patterns. A device pattern is formed in the substrate using directed self-assembly after the plurality of marks is formed.

In general, according to one embodiment, an overlay measurement system is configured to measure a positional relationship between a second mark and a mark having the highest identifiability of a plurality of first marks formed in a substrate. The plurality of first marks are made of mutually different patterns. A first device pattern is formed in the substrate using directed self-assembly after the plurality of first marks are formed. The second mark and a second device pattern are formed in the substrate after the first device pattern is formed.

In general, according to one embodiment, a method for manufacturing a semiconductor device includes forming a plurality of marks made of mutually different patterns on a substrate. The method includes forming a device pattern using directed self-assembly. The method includes measuring a position of a mark having the highest identifiability of the plurality of marks.

Embodiments of the invention will now be described with reference to the drawings.

First, a first embodiment will be described.

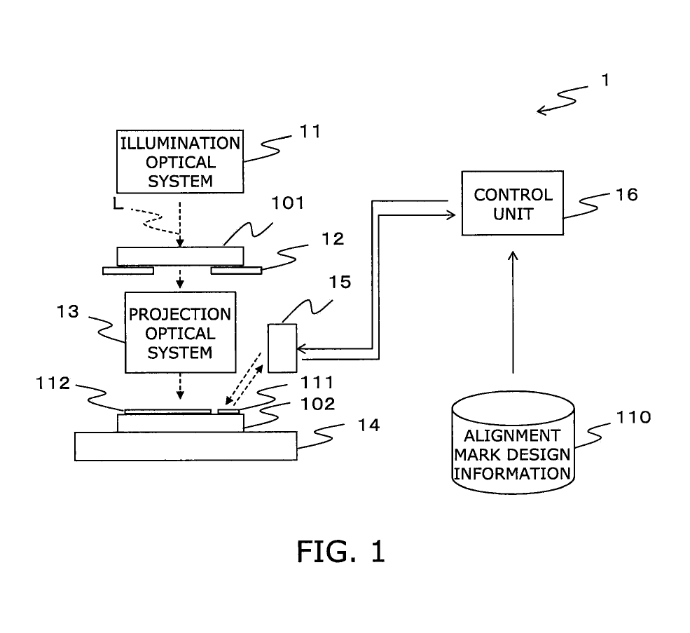

FIG. 1 is a block diagram showing an alignment measurement system according to the embodiment.

As shown in FIG. 1, the alignment measurement system 1 according to the embodiment is mounted in an exposure apparatus. In the alignment measurement system 1, an illumination optical system 11 that emits light L for exposing is provided; and a reticle stage 12, a projection optical system 13, and a wafer stage 14 are disposed in this order along the optical path of the light L. The reticle stage 12 is configured to hold a reticle 101 to be disposed in the optical path of the light L. The projection optical system 13 is configured to enlarge and project the light L passing through the reticle 101 and is, for example, a refractive optical system or a catadioptric optical system. The wafer stage 14 is configured to hold a wafer 102 at the position where the light L projected by the projection optical system 13 is imaged. An alignment mark 111 and a device pattern 112 are formed in the wafer 102.

An alignment measurement unit 15 and a control unit 16 are provided in the alignment measurement system 1. The alignment measurement unit 15 is configured to detect the alignment mark 111 formed in the wafer 102 by, for example, optical means. For example, the alignment measurement unit 15 may scan the alignment mark 111 with laser light and measure the diffraction ray of the laser light; or the alignment measurement unit 15 may image the alignment mark 111 with a bright field microscope. The control unit 16 controls the alignment measurement unit 15 based on alignment mark design information 110 input from the outside. Information such as the position where the alignment mark 111 is formed in the wafer 102, etc., is included in the alignment mark design information 110. The control unit 16 causes the alignment measurement unit 15 to detect the alignment mark 111 and selects an alignment mark having a high identifiability that can be identified most distinctly, e.g., the alignment mark having the highest signal contrast, based on the result. The control unit 16 measures the position of the alignment mark that is selected and generates an alignment signal based on the measurement result.

A method for manufacturing the semiconductor device according to the embodiment will now be described.

The method for manufacturing the semiconductor device according to the embodiment includes the operation of the alignment measurement system 1 described above.

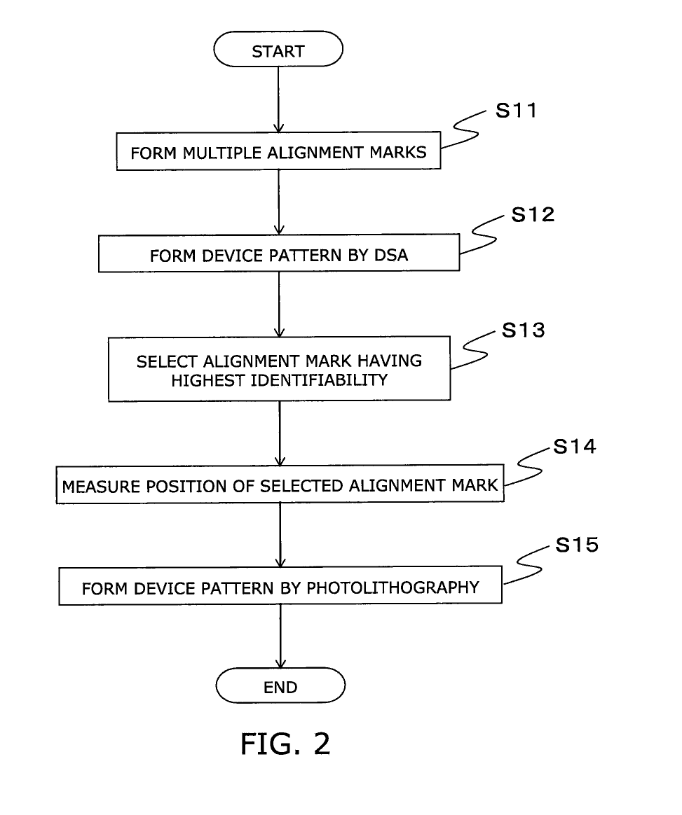

FIG. 2 is a flowchart showing the method for manufacturing the semiconductor device according to the embodiment.

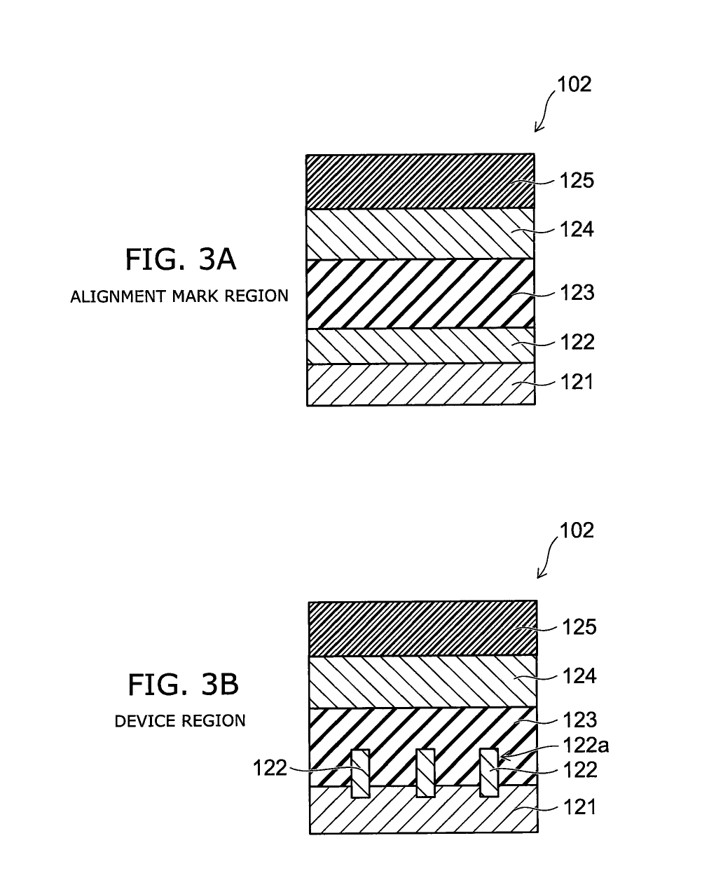

FIGS. 3A and 3B are cross-sectional views showing a wafer. FIG. 3A shows an alignment mark region; and FIG. 3B shows a device region.

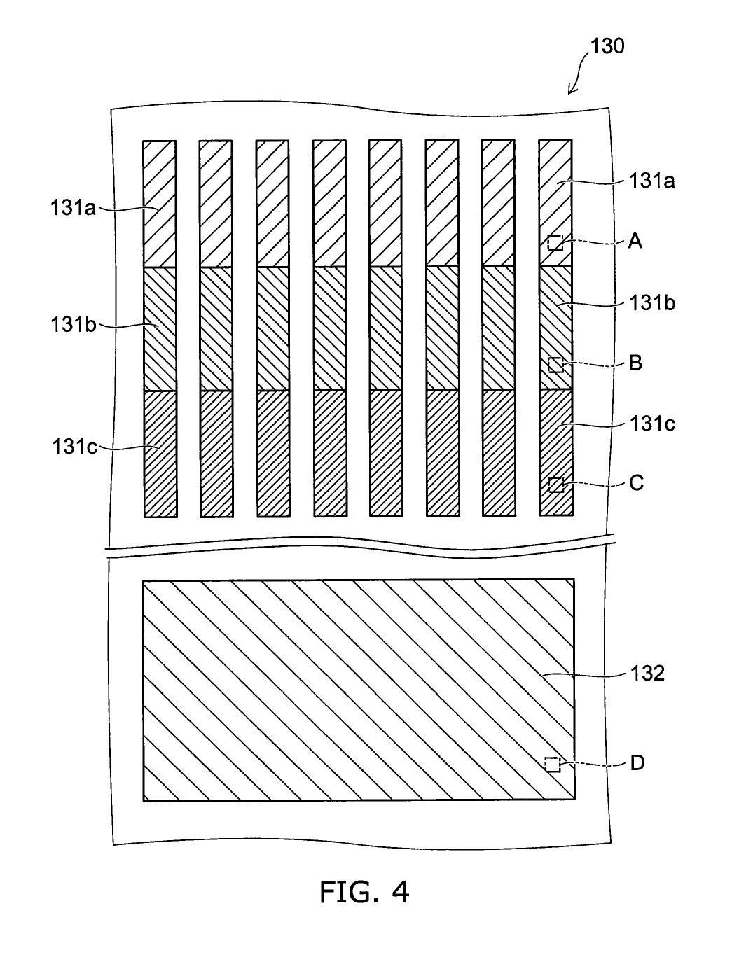

FIG. 4 is a plan view showing a reticle.

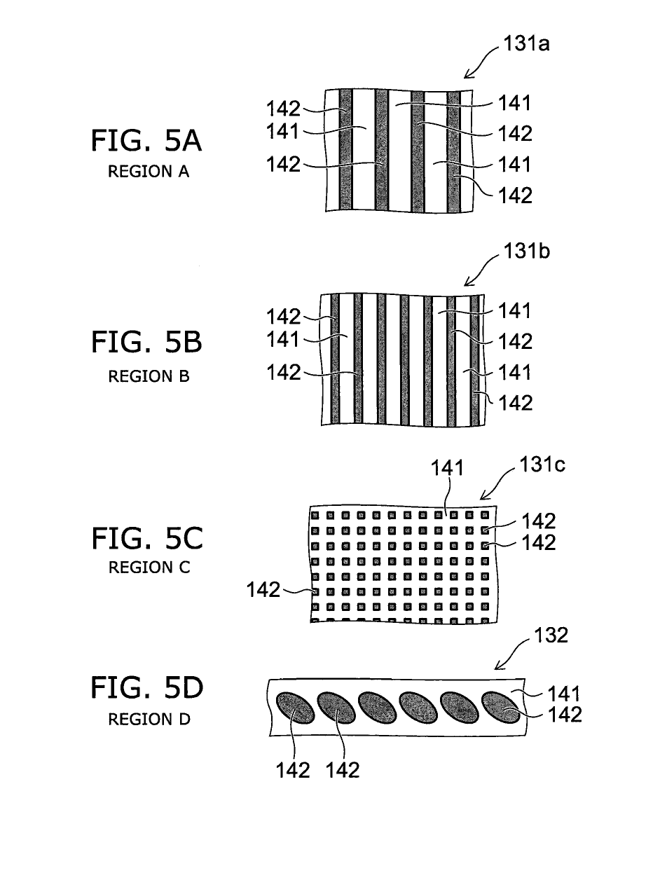

FIGS. 5A to 5D are plan views respectively showing the regions A to D shown in FIG. 4.

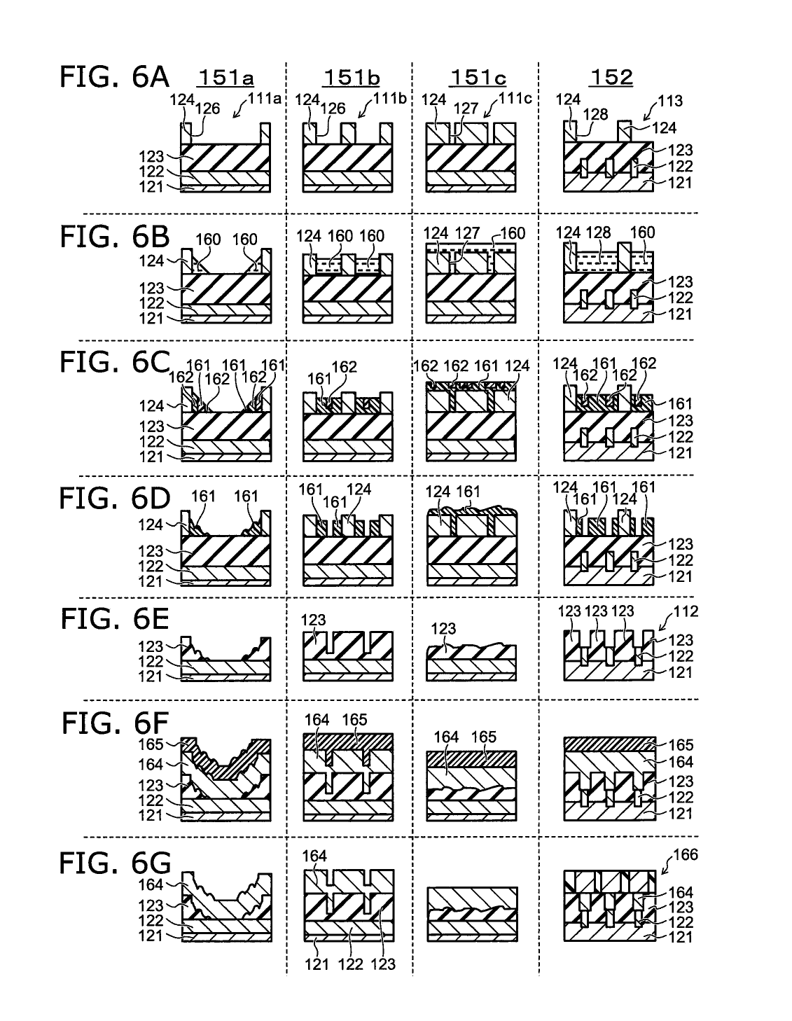

FIGS. 6A to 6G are schematic cross-sectional views showing the method for manufacturing the semiconductor device according to the embodiment.

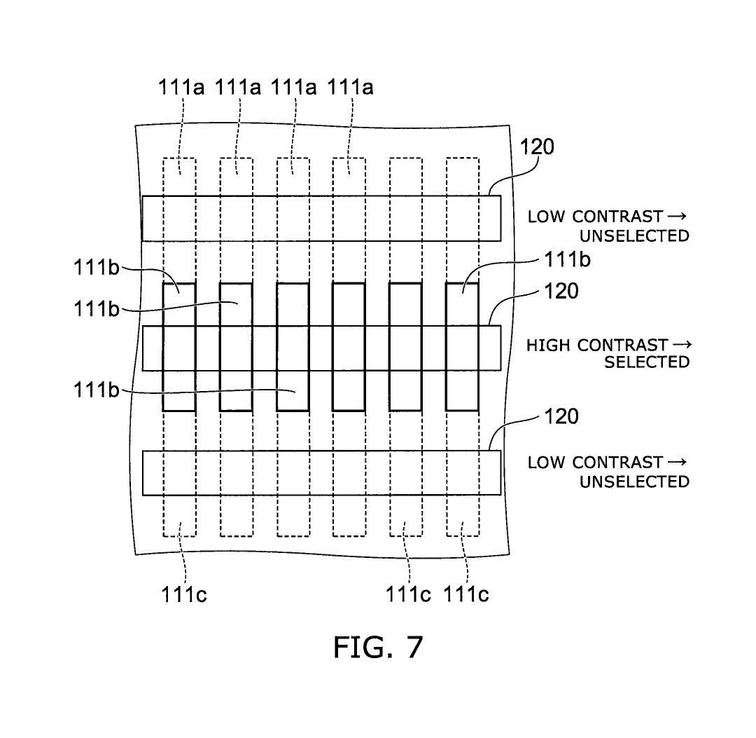

FIG. 7 is a plan view showing the alignment marks formed in the wafer.

First, multiple alignment marks are formed on the wafer 102 as shown in step S11 of FIG. 2. This process will now be described in detail.

As shown in FIGS. 3A and 3B, the wafer 102 prior to implementing step S11 includes, for example, a conductive film 122, an inter-layer insulating film 123, and a hard mask film 124 stacked in this order on a silicon wafer 121. As shown in FIG. 3A, a pattern is not formed in the conductive film 122 in the region (the alignment mark region) where the alignment mark 111 is to be formed. On the other hand, as shown in FIG. 3B, a device pattern 122a is formed in the conductive film 122 in the region (the device region) where the device pattern 112 is to be formed. The device pattern 122a is, for example, an interconnect pattern.

As shown in FIG. 4, three types of alignment marks 131a, 131b, and 131c are formed in a reticle 130 used in this process. A device pattern 132 also is set in the reticle 130. The configurations of the alignment marks 131a, 131b, and 131c are line configurations having multiple lines each. The direction in which the multiple alignment marks 131a extend, the direction in which the multiple alignment marks 131b extend, and the direction in which the multiple alignment marks 131c extend are the same and are parallel to the arrangement direction of the alignment marks 131a to 131c. The arrangement direction of the alignment marks 131a, the arrangement direction of the alignment marks 131b, and the arrangement direction of the alignment marks 131c are orthogonal to the arrangement direction of the alignment marks 131a to 131c.

As shown in FIGS. 5A to 5D, mutually different patterns are formed in the alignment marks 131a, 131b, and 131c. In other words, in the alignment mark 131a as shown in FIG. 5A, a pattern is formed in which transparent portions 141 and light-shielding portions 142 are arranged in a line-and-space configuration with a relatively large arrangement period. In the alignment mark 131b as shown in FIG. 5B, a pattern is formed in which the transparent portions 141 and the light-shielding portions 142 are arranged in a line-and-space configuration with a relatively small arrangement period. In the alignment mark 131c as shown in FIG. 5C, a pattern is formed in which the light-shielding portions 142 having multiple island configurations are arranged in a matrix configuration in the transparent portion 141. The dimensions and the arrangement periods of the transparent portions 141 and the light-shielding portions 142 of the alignment marks 131a to 131c have values such that the transparent portions 141 and the light-shielding portions 142 are not imaged by visible light, e.g., electromagnetic waves of wavelengths of 400 to 800 nm.

On the other hand, in the device pattern 132 as shown in FIG. 5D, the multiple light-shielding portions 142 are arranged in one column in the transparent portion 141. The configuration of each of the light-shielding portions 142 is, for example, an oval; and the major-axis direction of the oval is tilted with respect to the arrangement direction of the light-shielding portions 142. The dimensions and the arrangement period of the light-shielding portions 142 of the device pattern 132 also have values such that the light-shielding portions 142 normally are not imaged by visible light.

As shown in FIGS. 3A and 3B, a resist film 125 is formed on the wafer 102 described above. Then, the resist film 125 is exposed using the reticle 130. The exposure may be performed by the exposure apparatus shown in FIG. 1 or may be performed by another exposure apparatus. Then, the resist film 125 is developed. Thereby, the resist film 125 is selectively removed to form a resist pattern (not shown) on the hard mask film 124. The alignment marks 131a, 131b, and 131c of the reticle 130 are transferred onto the resist pattern in the alignment region of the wafer 102. The device pattern 132 of the reticle 130 is transferred onto the resist pattern in the device region.

Then, the hard mask film 124 is etched using the resist pattern as a mask. Thereby, as shown in FIG. 6A, alignment marks 111a to 111c and a guide pattern 113 for the DSA are formed in the hard mask film 124. Because the sizes of the alignment marks 131a to 131c formed in the reticle 130 are less than the resolution limit of visible light, the configurations of the alignment marks 111a to 111c transferred onto the hard mask film 124 do not always match the configurations of the alignment marks 131a to 131c formed in the reticle 130 but have configurations having constant correlations to the configurations of the alignment marks 131a to 131c. The configurations of the portions are drawn schematically in FIGS. 6A to 6G.

More specifically, in an alignment mark formation region 151a (hereinbelow, also called simply the region 151a) of the wafer 102 where the alignment marks 131a are transferred, the hard mask film 124 is divided into a line-and-space configuration; and the space between the divided hard mask films 124 is an opening 126. The arrangement period of the hard mask film 124 and the opening 126 is relatively large. Thereby, in the region 151a, the hard mask film 124 is arranged in a line-and-space configuration; and the alignment mark 111a is formed with a relatively large arrangement period.

In an alignment mark formation region 151b of the wafer 102 where the alignment marks 131b are transferred, the hard mask film 124 is divided into a line-and-space configuration. However, the arrangement period of the hard mask film 124 and the opening 126 is relatively small. Thereby, in the region 151b, the hard mask film 124 is arranged in a line-and-space configuration; and the alignment mark 111b is formed with a relatively small arrangement period.

Many holes 127 are formed in a matrix configuration in the hard mask film 124 in an alignment mark formation region 151c of the wafer 102 where the alignment marks 131c are transferred. Thereby, the alignment mark 111c having a collection of the holes 127 is formed in the hard mask film 124 in the region 151c. The alignment marks 111a to 111c also are generally referred to as the alignment mark 111.

On the other hand, multiple oval holes 128 are arranged in one column in the hard mask film 124 in a device pattern formation region 152 of the wafer 102 where the device pattern 132 is transferred. Thereby, in the region 152, the guide pattern 113 for the DSA in which the holes 128 are made in the hard mask film 124 is formed.

Then, as shown in step S12 of FIG. 2, a device pattern is formed using DSA. This process will now be described in detail.

As shown in FIG. 6B, a block copolymer solution 160 is coated onto the upper surface of the wafer 102. The coating is performed by, for example, spin coating. At this time, the thickness of the coating layer of the solution 160 greatly depends on the pattern density and the dimensions of the foundation. For example, in the case where the dimensions of the pattern are too large, the solution 160 adheres to only the edge portions of the pattern. In the case where the dimensions of the pattern are too small, the solution 160 undesirably flows out from the pattern. Also, in the case where the density of the pattern is too low, there are cases where sufficient contrast is not obtained when detecting the alignment marks in subsequent processes.

In this process, the coating conditions of the solution 160 are optimized to match the guide pattern 113 for the DSA. Therefore, the block copolymer solution 160 is appropriately filled into the oval holes 128 of the region 152. On the other hand, the conditions of the coating are not always optimized for the patterns of the alignment marks 111a to 111c formed in the alignment mark formation regions 151a to 151c. Therefore, the solution 160 is not always coated appropriately in the regions 151a to 151c.

In the embodiment, it is taken that the solution 160 is appropriately filled into the opening 126 in the region 151b. Conversely, in the region 151a, the solution 160 remains at only the corner portions between the inter-layer insulating film 123 and the hard mask film 124 in the opening 126 because the opening 126 is too wide. In the region 151c, the solution 160 is filled into the hole 127 and flows out from the hole 127 to undesirably cover the entire upper surface of the hard mask film 124 because the hole 127 is too small.

Then, as shown in FIG. 6C, the block copolymer solution 160 is caused to undergo micro phase separation by performing, for example, heat treatment. Thereby, the solution 160 separates into a block 161 made of a first phase and a block 162 made of a second phase and is cured. The solution 160 and the conditions of the coating and the phase separation of the solution 160 are selected such that the basic period of the phase separation matches the dimensions of the holes 128 of the device pattern formation region 152. At this time, the basic period of the phase separation also matches the dimensions of the opening 126 of the alignment mark formation region 151b. Therefore, the block 161 and the block 162 are regularly arranged in the device pattern formation region 152 and the alignment mark formation region 151b. On the other hand, in the alignment mark formation regions 151a and 151c, the phase separation is not controlled and the block 161 and the block 162 are arranged irregularly because the size of the coating layer of the solution 160 does not match the basic period of the phase separation of the solution 160.

Then, as shown in FIG. 6D, the block 162 is selectively removed with the block 161 left as-is. At this time, although the block 161 remains in a regular form in the regions 152 and 151b, the block 161 remains in an irregular form in the regions 151a and 151c.

Continuing as shown in FIG. 6E, the inter-layer insulating film 123 is selectively removed by performing anisotropic etching such as, for example, RIE (Reactive Ion Etching) using the hard mask film 124 and the block 161 as a mask. Thereby, the pattern made of the hard mask film 124 and the block 161 is transferred onto the inter-layer insulating film 123. As a result, the inter-layer insulating film 123 is selectively removed and the device pattern 112 is formed in the device pattern formation region 152. The device pattern 112 is, for example, a pattern of contact holes.

Then, as shown in step S13 of FIG. 2, the alignment mark having the highest identifiability of the alignment marks 111a to 111c is selected. This process will now be described in detail.

As shown in FIG. 6F, a conductive film 164 is formed on the entire surface of the inter-layer insulating film 123. At this time, in the alignment mark formation regions 151a to 151c, the configuration of the upper surface of the conductive film 164 reflects the configuration of the upper surface of the inter-layer insulating film 123. In the region 151b, the correlation between the configuration of the upper surface of the conductive film 164 and the pattern of the alignment mark 111b is high because the block 161 remains in a regular form in the process shown in FIG. 6D. Conversely, in the regions 151a and 151c, the correlation between the configuration of the upper surface of the conductive film 164 and the patterns of the alignment marks 111a and 111c is low because the block 161 remains in an irregular form in the process shown in FIG. 6D. On the other hand, in the device pattern formation region 152, the conductive film 164 is filled into the contact holes made in the inter-layer insulating film 123 and forms a continuous film above the inter-layer insulating film 123. Then, a resist film 165 is formed on the conductive film 164.

Continuing, the wafer 102 in the state shown in FIG. 6F is placed into the exposure apparatus in which the alignment measurement system 1 shown in FIG. 1 is mounted. The alignment mark design information 110 is input to the control unit 16 of the alignment measurement system 1. Thereby, the control unit 16 controls the alignment measurement unit 15 based on the alignment mark design information 110; and the alignment measurement unit 15 detects the alignment marks 111a to 111c by, for example, optically viewing the upper surface of the conductive film 164.

As shown in FIG. 1 and FIG. 7, for example, the alignment measurement unit 15 scans a measurement region 120 of the alignment mark 111 with laser light and measures the diffraction ray of the laser light. Or, the alignment measurement unit 15 images the measurement region 120 of the alignment mark 111 with a bright field microscope. The control unit 16 selects the alignment mark having the highest identifiability, e.g., the alignment mark having the highest signal contrast, based on the detection result of the alignment measurement unit 15.

For example, in the embodiment, the identifiability of the alignment mark 111b is high because the pattern of the alignment mark 111b is reflected with relatively good precision on the upper surface of the conductive film 164. At this time, although the control unit 16 cannot detect the basic pattern of the alignment mark, i.e., each of the patterns of one hard mask film 124 and one opening 126, the control unit 16 can detect the entire alignment mark 111b. Conversely, the identifiability of the alignment marks 111a and 111c is low because the patterns of the alignment marks 111a and 111c are not reflected with good precision in the configuration of the upper surface of the conductive film 164.

Accordingly, the control unit 16 selects the alignment mark 111b. Which of the alignment marks will have the highest identifiability depends on the materials of the inter-layer insulating film 123 and the hard mask film 124, the type of the block copolymer solution 160, the coating conditions of the solution 160, the phase separation conditions, etc., and therefore fluctuates within the batch and between batches and is difficult to predict beforehand. Therefore, the alignment mark having the highest identifiability is selected after measuring all of the alignment marks 111a to 111c each time.

Then, as shown in step S14 of FIG. 2, the position of the alignment mark 111 is measured. Specifically, the control unit 16 measures the position of the end edge of the alignment mark 111b selected in the process shown in step S13. Then, the alignment signal is generated based on the measurement result.

Continuing as shown in step S15 of FIG. 2, the device pattern is formed by photolithography. This process will now be described in detail.

As shown in FIG. 1, the control unit 16 disposes the wafer 102 at the appropriate position by moving the wafer stage 14 based on the alignment signal that is generated. Then, the illumination optical system 11 emits the light L. The light L selectively passes through the reticle 101, is enlarged by the projection optical system 13, and is projected onto the wafer 102. Thereby, the resist film 165 is exposed. Then, a resist pattern (not shown) is formed by developing the resist film 165.

Then, as shown in FIG. 6G, a device pattern 166 is formed in the device pattern formation region 152 using the resist pattern. The device pattern 166 is, for example, an interconnect pattern. The device pattern 166 matches the device pattern 112. Thereafter, the semiconductor device is manufactured by normal processes.

Effects of the embodiment will now be described.

According to the embodiment, the multiple alignment marks 111a to 111c having mutually different patterns are formed in the process shown in step S11 of FIG. 2 and FIG. 6A. Then, the device pattern 112 is formed using DSA in the process shown in step S12 and FIGS. 6B to 6E. At this time, the form of the alignment mark 111 changes due to effects of the coating and the phase separation of the block copolymer solution 160. However, because the change of the form differs according to the pattern of the alignment mark 111, there is a high possibility that a recognizable state can be maintained for one selected from the alignment marks 111a to 111c. Therefore, if the alignment mark 111 having the highest identifiability is selected in the process shown in step S13, the position of the alignment mark 111 can be detected with good precision in the process shown in step S14 and FIG. 6F. As a result, the device pattern 166 can be formed at the appropriate position with respect to the device pattern 112 in the process shown in step S15 and FIG. 6G. Thus, in the manufacturing process of the semiconductor device, the alignment between the device pattern 112 and the device pattern 166 can be performed with good precision even in the case where DSA is used. As a result, the yield of the semiconductor device can be increased.

Conversely, if only one type of alignment mark is formed, the position of the alignment mark cannot be accurately measured in the case where the identifiability undesirably decreases due to the alignment mark being sullied by the block copolymer solution. Although it may be considered to form multiple alignment marks having mutually different patterns and predetermine the alignment mark for which the position is to be measured, it is difficult to know beforehand which alignment mark will have the highest identifiability because the effects of the DSA on the identifiability of the alignment mark are different each time due to the various conditions.

A second embodiment will now be described.

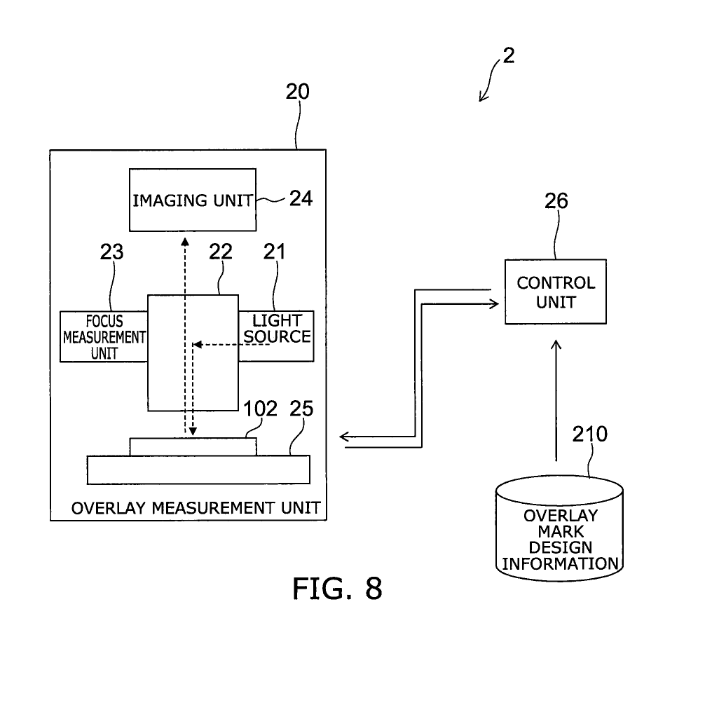

FIG. 8 is a block diagram showing an overlay measurement system according to the embodiment.

As shown in FIG. 8, an overlay measurement unit 20 is provided in an overlay measurement system 2 according to the embodiment. A light source 21, a microscope optical system 22, a focus measurement unit 23, an imaging unit 24, and a wafer stage 25 are provided in the overlay measurement unit 20. The wafer stage 25 is a member that holds the wafer 102. The imaging unit 24 includes, for example, a CCD (Charge Coupled Device) camera. These components are disposed at positions such that the light emitted from the light source 21 is irradiated by the microscope optical system 22 onto the wafer 102 held by the wafer stage 25; and the light reflected by the wafer 102 is incident on the focus measurement unit 23 and the imaging unit 24 via the microscope optical system 22. The focus measurement unit 23 detects the focus of the microscope optical system 22 and adjusts the microscope optical system 22; and the imaging unit 24 images the enlarged image of the wafer 102.

A control unit 26 is provided in the overlay measurement system 2. Image data from the imaging unit 24 is input to the control unit 26; and overlay mark design information 210 from the outside is input to the control unit 26. The overlay mark design information 210 includes design information of the alignment marks 111a to 111c (referring to the drawings) and a litholayer mark 116 (referring to the drawings) of the wafer 102. The control unit 26 detects the alignment marks 111a to 111c and the litholayer mark 116 by controlling the overlay measurement unit 20 based on the overlay mark design information 210. The control unit 26 selects the alignment mark having the highest identifiability, e.g., the alignment mark having the highest signal contrast, of the alignment marks 111a to 111c. Then, the control unit 26 measures the position of the litholayer mark 116 and the position of the alignment mark 111 that is selected.

A method for manufacturing the semiconductor device according to the embodiment will now be described.

The method for manufacturing the semiconductor device according to the embodiment includes the operation of the overlay measurement system 2 described above.

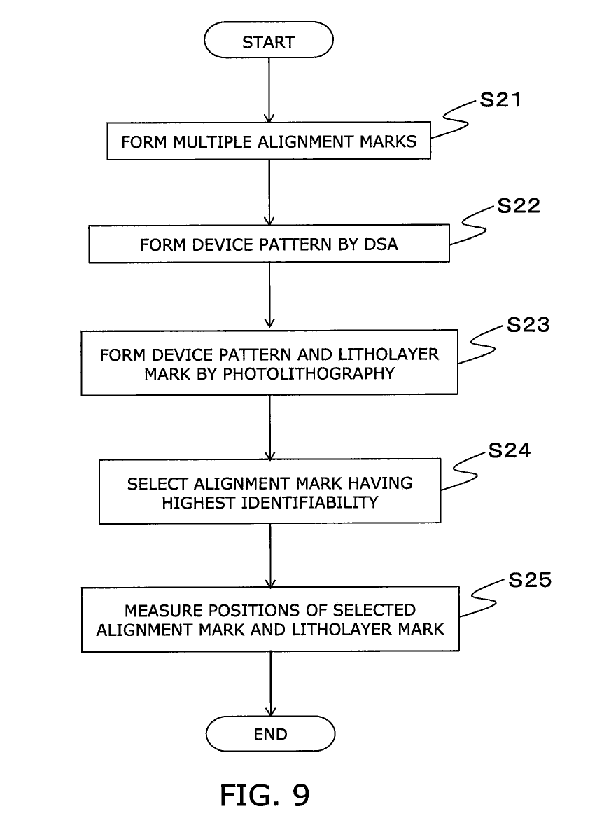

FIG. 9 is a flowchart showing the method for manufacturing the semiconductor device according to the embodiment.

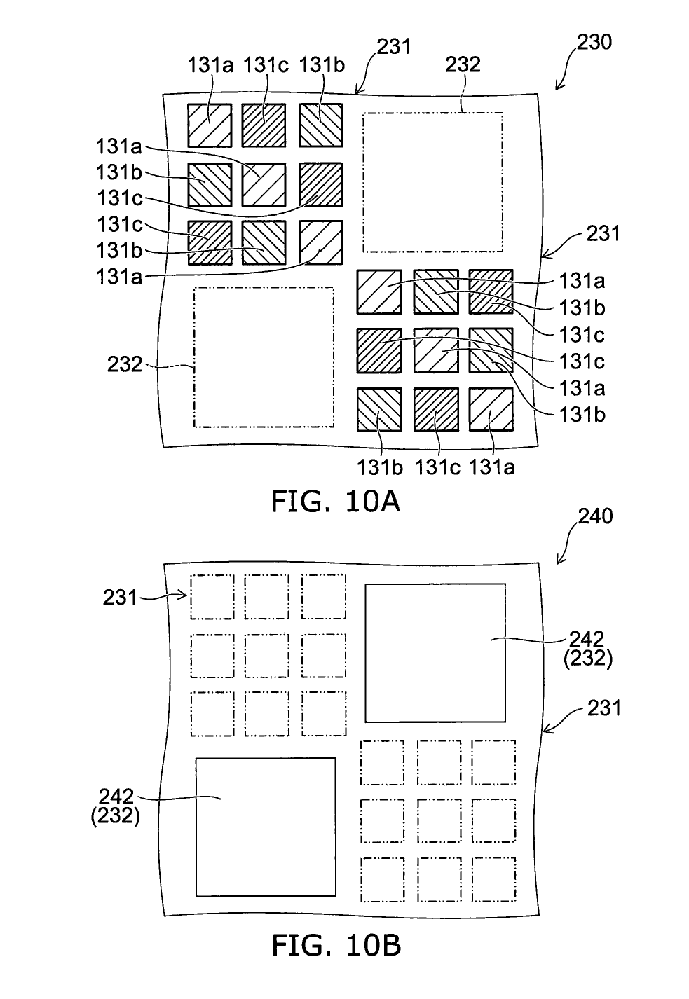

FIG. 10A is a plan view showing the reticle when forming the alignment marks; and FIG. 10B is a plan view showing the reticle when forming the litholayer marks.

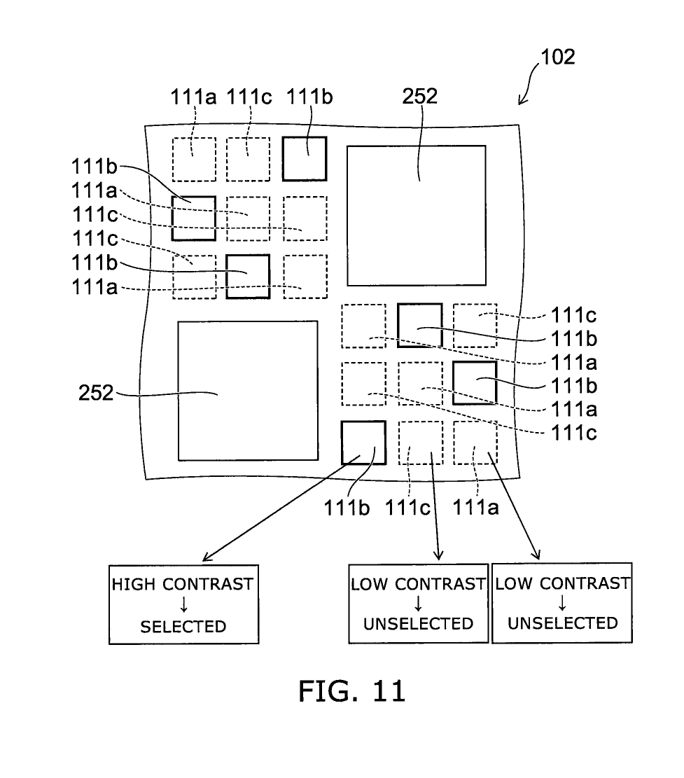

FIG. 11 is a plan view showing the alignment marks and the litholayer marks formed in the wafer.

First, as shown in step S21 of FIG. 9, the multiple alignment marks 111a to 111c (referring to FIG. 6A) are formed in the wafer 102 as first alignment marks. The process shown in step S21 is similar to the process shown in step S11 of FIG. 2 and FIG. 6A of the first embodiment described above. However, the reticle 230 shown in FIG. 10A is used in the process shown in step S21.

In the reticle 230, alignment mark regions 231 and litholayer mark regions 232 are arranged in a staggered configuration; and the rectangular alignment marks 131a to 131c are arranged in a matrix configuration in each of the alignment mark regions 231. The pattern configurations of the alignment marks 131a to 131c are as shown in FIGS. 5A to 5C. Patterns are not formed in the litholayer mark regions 232. A device region (not shown) also is set in the reticle 230. The device pattern 132 (referring to FIG. 5D) is formed in the device region.

Then, as shown in step S22 of FIG. 9, a device pattern is formed using DSA. The process shown in step S22 is similar to the process shown in step S12 of FIG. 2 and FIGS. 6B to 6E of the first embodiment described above. Thereby, the device pattern 112 is formed in the device pattern formation region 152 of the wafer 102.

Continuing as shown in step S23 of FIG. 9, a device pattern and the litholayer marks are formed using photolithography. This process will now be described in detail.

As shown in FIG. 10B, similarly to the reticle 230, the alignment mark regions 231 and the litholayer mark regions 232 are arranged in a staggered configuration in a reticle 240 used in this lithography process. Patterns are not formed in the alignment mark regions 231; and litholayer marks 242 are formed in the litholayer mark regions 232. The patterns of the litholayers marks 242 are large enough to be resolved by visible light. A device region (not shown) also is set in the reticle 240. A pattern corresponding to the device pattern 166 (referring to FIG. 6G) is formed in the device region.

Then, a resist pattern (not shown) is formed by exposing and developing the resist film 165 (referring to FIG. 6F) using the reticle 240. Continuing, patterning processing such as etching, etc., is performed using the resist pattern.

Thereby, as shown in FIG. 11, the device pattern 166 is formed to be overlaid on the device pattern 112 in the device pattern formation region 152 of the wafer 102; and litholayer marks 252 are formed proximally to the alignment marks 111a to 111c in the alignment mark formation regions 151a to 151c.

Then, as shown in step S24 of FIG. 9, the alignment mark having the highest identifiability of the alignment marks 111a to 111c is selected.

Specifically, the wafer 102 is placed in the overlay measurement system 2 shown in FIG. 8. The overlay mark design information 210 is input to the control unit 26 of the overlay measurement system 2. Thereby, the control unit 26 controls the overlay measurement unit 20 based on the overlay mark design information 210. In other words, the wafer stage 25 moves to position the regions of the wafer 102 where the alignment mark 111 and the litholayer mark 252 are formed at the viewing position of the microscope optical system 22. Then, the light source 21 emits light; the light is irradiated on the wafer 102 via the microscope optical system 22; and the light reflected by the wafer 102 is incident on the focus measurement unit 23 and the imaging unit 24 via the microscope optical system 22. Thereby, the imaging unit 24 images the enlarged image of the wafer 102 while the focus measurement unit 23 performs the focusing. Then, the data of the image that is imaged is output to the control unit 26.

Then, as shown in FIG. 11, the control unit 26 selects the alignment mark having the highest identifiability, e.g., the alignment mark having the highest signal contrast, of the alignment marks 111a to 111c based on the image data that is input. In the embodiment, as described above, the control unit 26 selects the alignment mark 111b because the contrast of the alignment marks 111a and 111c is low and the contrast of the alignment mark 111b is high.

Continuing as shown in step S25 of FIG. 9, the control unit 26 measures the position of the litholayer mark 252 and the position of the alignment mark 111b that is selected. Then, the relative positional relationship between the alignment mark 111b and the litholayer mark 252 is evaluated based on the measurement result. Continuing, the overlay of the device pattern 112 and the device pattern 166 is determined to be good if the shift between the positions of the alignment mark 111b and the litholayer mark 252 is within a tolerance range; and the overlay is determined to be unacceptable if the shift between the positions exceeds the tolerance range. Thereafter, the semiconductor device is manufactured by normal processes.

Effects of the embodiment will now be described.

According to the embodiment, the multiple alignment marks 111a to 111c (referring to FIG. 6A) having different patterns are formed in the process shown in step S21 of FIG. 9. Thereby, when the device pattern 112 is formed using DSA in the process shown in step S22, there is a high possibility that the recognizable state of one selected from the alignment marks 111 can be maintained even in the case where the identifiability decreases due to the alignment mark 111 being affected by the coating of the block copolymer solution 160 (referring to FIG. 6B) and the phase separation (referring to FIG. 6C) because the degree of the decrease of the identifiability differs according to the pattern of the alignment mark 111.

Therefore, an evaluation having high precision is possible when evaluating the positional relationship between the alignment mark 111 and the litholayer mark 252 in the process shown in step S25 if the alignment mark 111 having the highest identifiability is selected in the process shown in step S24 after forming the device pattern 166 (referring to FIG. 6G) and the litholayer mark 252 (referring to FIG. 11) in the process shown in step S23. As a result, in the manufacturing process of the semiconductor device, the goodness determination of the overlay of the device pattern 112 and the device pattern 166 can be performed with good precision even in the case where DSA is used. Otherwise, the configuration, the operations, and the effects of the embodiment are similar to those of the first embodiment described above.

Although an example in which the three types of alignment marks 111a to 111c are formed is shown in the first and second embodiments described above, the alignment mark is not limited to three types; and two, four, or more types may be used. The configuration, the dimensions, and the pattern of the alignment mark are arbitrary. For example, the basic period of the device pattern 112 formed by DSA may be used as a reference; one of the alignment marks may be a pattern having the same period as the basic period; and the other two alignment marks may be patterns having periods of ±10% or ±20% of the basic period.

Although an example in which the reticle 101 is a transmission type and the projection optical system 13 is a refractive optical system or a catadioptric optical system is illustrated in the exposure apparatus shown in FIG. 1, this is not limited thereto; and the optical system including the reticle may be a reflection type. The alignment measurement system 1 may be mounted not in the exposure apparatus but in a nanoimprint apparatus.

According to the embodiments described above, an alignment measurement system, an overlay measurement system, and a method for manufacturing a semiconductor device that can accurately detect the position of the alignment mark even after processing by directed self-assembly can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. An alignment measurement system configured to measure a position of a mark having the highest identifiability of a plurality of marks formed in a substrate, the plurality of marks being made of mutually different patterns, a device pattern being formed in the substrate using directed self-assembly after the plurality of marks is formed.

2. The system according to claim 1, wherein patterns having line-and-space configurations having mutually different arrangement periods are formed in two of the plurality of marks.

3. The system according to claim 1, wherein a pattern having a line-and-space configuration is formed in one of the plurality of marks, and a pattern having a collection of holes is formed in one other of the plurality of marks.

4. The system according to claim 1, wherein a first mark, a second mark, and a third mark are formed as the plurality of marks, the first mark including a pattern having a line-and-space configuration, the second mark including a pattern having a line-and-space configuration having an arrangement period larger than an arrangement period of the pattern of the first mark, the third mark including a pattern having a collection of holes.

5. The system according to claim 1 mounted in an exposure apparatus.

6. An overlay measurement system configured to measure a positional relationship between a second mark and a mark having the highest identifiability of a plurality of first marks formed in a substrate, the plurality of first marks being made of mutually different patterns, a first device pattern being formed in the substrate using directed self-assembly after the plurality of first marks are formed, the second mark and a second device pattern being formed in the substrate after the first device pattern is formed.

7. The system according to claim 6, wherein patterns having line-and-space configurations having mutually different arrangement periods are formed in two of the plurality of first marks.

8. The system according to claim 6, wherein a pattern having a line-and-space configuration is formed in one of the plurality of first marks, and a pattern having a collection of holes is formed in one other of the plurality of first marks.

9. The system according to claim 6, wherein a narrow mark, a wide mark, and a hole mark are formed as the plurality of first marks, the narrow mark including a pattern having a line-and-space configuration, the wide mark including a pattern having a line-and-space configuration having an arrangement period larger than an arrangement period of the pattern of the narrow mark, the hole mark including a pattern having a collection of holes.

10. A method for manufacturing a semiconductor device, comprising:
forming a plurality of marks made of mutually different patterns on a substrate;
forming a device pattern using directed self-assembly; and
measuring a position of a mark having the highest identifiability of the plurality of marks.

11. The method according to claim 10, further comprising forming one other mark and one other device pattern after the forming of the device pattern,
the measuring of the position of the mark including measuring a positional relationship between the mark and the one other mark.

12. The method according to claim 10, wherein the forming of the plurality of marks includes forming patterns having line-and-space configurations having mutually different arrangement periods in two of the plurality of marks.

13. The method according to claim 10, wherein the forming of the plurality of marks includes forming a pattern having a line-and-space configuration in one of the plurality of marks and forming a pattern having a collection of holes in one other of the plurality of marks.

14. The method according to claim 10, wherein the forming of the plurality of marks includes forming a first mark, a second mark, and a third mark, the first mark including a pattern having a line-and-space configuration, the second mark including a pattern having a line-and-space configuration having an arrangement period larger than an arrangement period of the pattern of the first mark, the third mark including a pattern having a collection of holes.
